(19) United States
(12) Patent Application Publication
(10) Pub. No.: US 2017/0184684 A1
(43) Pub. Date: Jun. 29, 2017

(54) JUDGMENT DEVICE, PROGRAM, JUDGMENT METHOD IN JUDGMENT DEVICE, AND PRINTER

(71) Applicant: Seiko Epson Corporation, Tokyo (JP)

(72) Inventor: Noriaki Murayama, Azumino-shi (JP)

(21) Appl. No.: 15/380,554

(22) Filed: Dec. 15, 2016

(30) Foreign Application Priority Data
Dec. 25, 2015 (JP) 2015-253625

(51) Int. Cl. G01R 31/36; B41J 23/00; B41J 3/407

(52) U.S. Cl. CPC G01R 31/3693; B41J 3/4075; B41J 23/00; G01R 31/3651; G01R 31/3689

(57) ABSTRACT

A judgment device includes a residual capacity acquisition section adapted to obtain a remaining battery power of a battery as a power source of a printer, an arithmetic section adapted to calculate a predicted consuming capacity of the battery consumed by execution of a print job, and a judgment section adapted to judge whether or not the battery has the remaining battery power, with which the printer can complete the print job, based on the remaining battery power and the predicted consuming capacity.

### BACKGROUND

1. Technical Field

The present invention relates to a judgment device, a program, a judgment method in the judgment device, and a printer each for judging whether or not the printer can complete a print job.

2. Related Art

In the past, there has been known a printer which judges, in the case in which the number of print sheets in a print job is equal to or smaller than a predetermined number of sheets, and the residual capacity of a battery is equal to or higher than a predetermined threshold value, that the print job can be completed (see JP-A-2014-188931).

The inventors found out the following problem. In the related art printer, it is judged without exception, in the case in which the number of print sheets in a print job is equal to or smaller than a predetermined number of sheets, and the residual capacity of a battery is equal to or higher than a predetermined threshold value, that the print job can be completed. Therefore, in the case in which the consumed power of the battery consumed by the print job of a predetermined number of sheets becomes higher than usual in accordance with the print density or the like, there is a possibility that it is faultily judged that the print job can be completed despite that the print job cannot be completed.

### SUMMARY

An advantage of the invention is to provide a judgment device, a program, a judgment method in the judgment device, and a printer each capable of preventing a printer from faultily judging that the print job can be completed.

A judgment device according to an aspect of the invention includes a residual capacity acquisition section adapted to obtain a remaining battery power of a battery as a power source of a printer, an arithmetic section adapted to calculate a predicted consuming capacity of the battery consumed by execution of a print job, and a judgment section adapted to judge whether or not the battery has the remaining battery power, with which the printer can complete the print job, based on the remaining battery power and the predicted consuming capacity.

A judgment method in a judgment device according to another aspect of the invention includes the steps of obtaining a remaining battery power of a battery as a power source of a printer, calculating a predicted consuming capacity of the battery consumed by execution of a print job, and judging whether or not the battery has the remaining battery power, with which the printer can complete the print job, based on the remaining battery power and the predicted consuming capacity.

A printer according to another aspect of the invention includes a printing section adapted to perform printing on a print medium, a residual capacity acquisition section adapted to obtain a remaining battery power of a battery as a power source, an arithmetic section adapted to calculate a predicted consuming capacity of the battery consumed by execution of a print job, and a judgment section adapted to judge whether or not the battery has the remaining battery power, with which the print job can be completed, based on the remaining battery power and the predicted consuming capacity.

According to the configuration described above, based on the predicted consuming capacity calculated by the arithmetic section, whether or not the battery has the remaining battery power with which the printer can complete the print job is judged by the judgment section. Thus, even in the case in which the predicted consuming capacity varies in accordance with the content of the print job, whether or not the battery has the remaining battery power with which the printer can complete the print job can appropriately be judged. Therefore, according to the present configuration, it is possible to prevent the printer from faultily judging that the print job can be completed.

In the judgment device described above, it is preferable that the arithmetic section calculates the predicted consuming capacity based on a print density in the print job.

According to this configuration, even in the case in which the predicted consuming capacity varies in accordance with the print density, the predicted consuming capacity can appropriately be calculated.

In this case, it is preferable that the arithmetic section calculates the predicted consuming capacity based on a number of times of a cutting process adapted to cut a print medium in the print job.

According to this configuration, even in the case in which the predicted power consumption varies in accordance with the number of times of the cutting process, the predicted consuming capacity can appropriately be calculated.

In this case, it is preferable that there is further included a threshold value acquisition section adapted to obtain a residual capacity threshold value, and the judgment section makes a judgment on whether or not a predicted residual capacity as a difference obtained by subtracting the predicted consuming capacity from the remaining battery power is one of equal to and higher than the residual capacity threshold value as the judgment on whether or not the battery has the remaining battery power with which the printer can complete the print job.

According to this configuration, in the case in which the predicted residual capacity is equal to or higher than the residual capacity threshold value, it is judged that the battery has the remaining battery power with which the printer can complete the print job. Further, in the case in which the predicted residual capacity is lower than the residual capacity threshold value, it is judged that the battery fails to have the remaining battery power with which the printer can complete the print job.

In this case, it is preferable that the threshold acquisition section obtains the residual capacity threshold value different between types of the battery.

According to this configuration, as the residual capacity threshold value, the value added with the discharge characteristic of the battery can be obtained.

In this case, it is preferable that the residual capacity acquisition section obtains the remaining battery power while performing printing on n-th label (n is an integer no smaller than 1) out of the print job of performing printing on a plurality of labels, the arithmetic section calculates a value consumed by execution of the print job of performing printing on an (n+1)-th label and following labels as the predicted consuming capacity, and the judgment section judges whether or not the battery has the remaining battery power with which the printer can complete the print job of performing printing on the (n+1)-th label and the following labels based on the remaining battery power obtained while performing printing on the n-th label, and the predicted consuming capacity.

According to this configuration, the remaining battery power is obtained in real time while performing printing on the plurality of labels. Therefore, according to the present configuration, whether or not the battery has the remaining battery power with which the printer can complete the print job can more appropriately be judged.

In this case, it is preferable that there is further included an annunciation section adapted to give a message in a case in which the judgment section judges that the battery fails to have the remaining battery power with which the printer can complete the print job.

According to this configuration, it is possible to notify the user of the fact that the battery fails to have the remaining battery power with which the printer 1 can complete the print job.

A program according to another aspect of the invention is for making an information processing device function as the judgment device described above.

### BRIEF DESCRIPTION OF THE DRAWINGS

The invention will be described with reference to the accompanying drawings, wherein like numbers reference like elements.

FIG. 1 is an external view of a print system provided with an information processing device according to an embodiment of the invention.

FIG. 2 is a diagram showing a character input screen.

FIG. 3 is a diagram showing a configuration screen.

FIG. 4 is a block diagram of a print system.

FIG. 5 is a diagram for explaining a residual capacity threshold value table.

FIG. 6 is a diagram for explaining a power consumption table.

FIG. 7 is a diagram for explaining a print density factor table.

FIG. 8 is a diagram for explaining a print color density factor table.

FIG. 9 is a diagram for explaining a print speed factor table.

FIG. 10 is a diagram for explaining an environmental temperature factor table.

FIG. 11 is a diagram showing a functional configuration of a processing-side control circuit.

FIG. 12 is a flowchart showing a processing sequence of the processing-side control circuit after starting up corresponding software.

FIG. 13 is a flowchart following the flowchart shown in FIG. 12.

FIG. 14 is a flowchart showing a remaining battery power judgment process.

### DESCRIPTION OF AN EXEMPLARY EMBODIMENT

Hereinafter, an embodiment of the invention will be described with reference to the accompanying drawings.

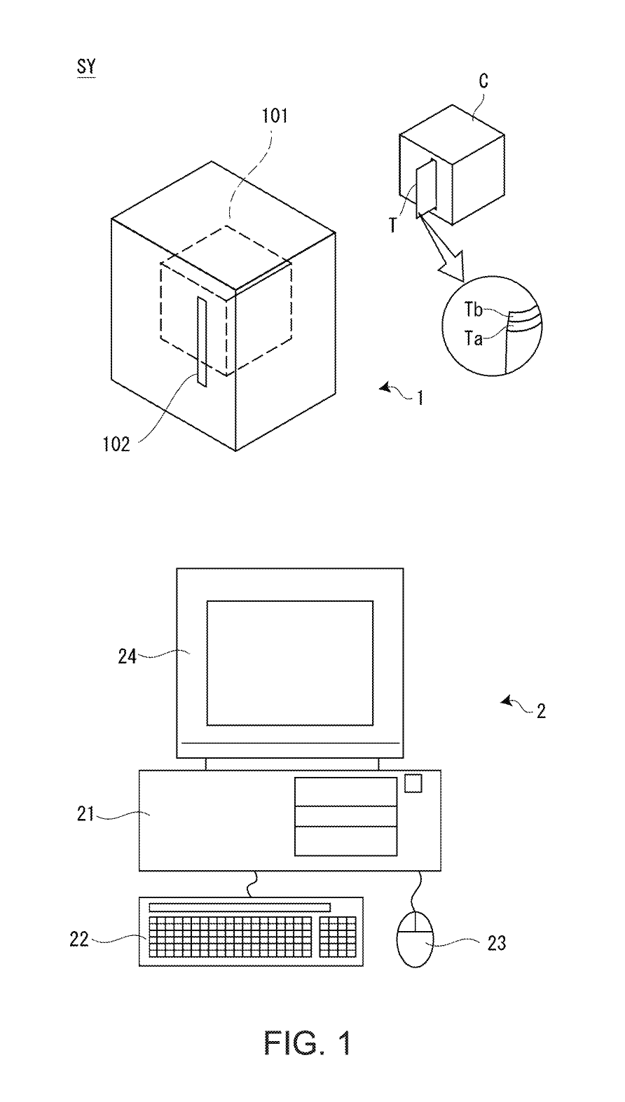

Based on FIG. 1, a print system SY provided with an information processing device 2 according to the embodiment of the invention will be described. The print system SY is provided with a tape printer 1 and an information processing device 2. The tape printer 1 and the information processing device 2 are connected to each other wirelessly or with wire so as to be able to communicate with each other.

The tape printer 1 is provided with a cartridge mount 101 and a tape discharge port 102. The tape printer 1 performs printing and cutting on a tape T in a tape cartridge C mounted on the cartridge mount 101 based on the print data received from the information processing device 2. The tape T is provided with a tape main body Ta on which a print image is printed, and release paper Tb detachably attached to an adhesive surface of the tape main body Ta. Among the parts of the tape T discharged from the tape discharge port 102, the tape main body Ta peeled from the release paper Tb is attached to a desired place.

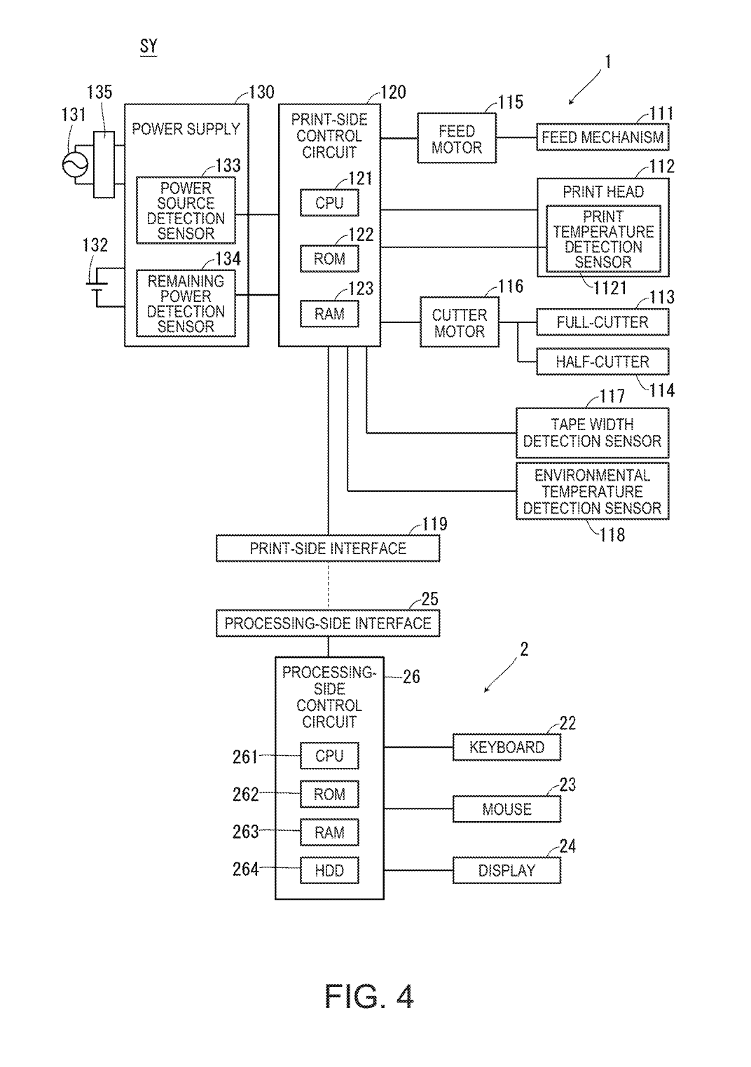

As the tape cartridge C, there is prepared a plurality of types different in tape width of the tape T housed in the tape cartridge. Therefore, the cartridge mount 101 is provided with a tape width detection sensor 117 (see FIG. 4).

Further, although not shown in the drawings, the tape printer 1 is provided with an adapter insertion port and a battery mount. To the adapter insertion port, there is inserted an AC adapter 135 (see FIG. 4). To the battery mount, there is attached a plurality of batteries 132 (see FIG. 4) in series to each other.

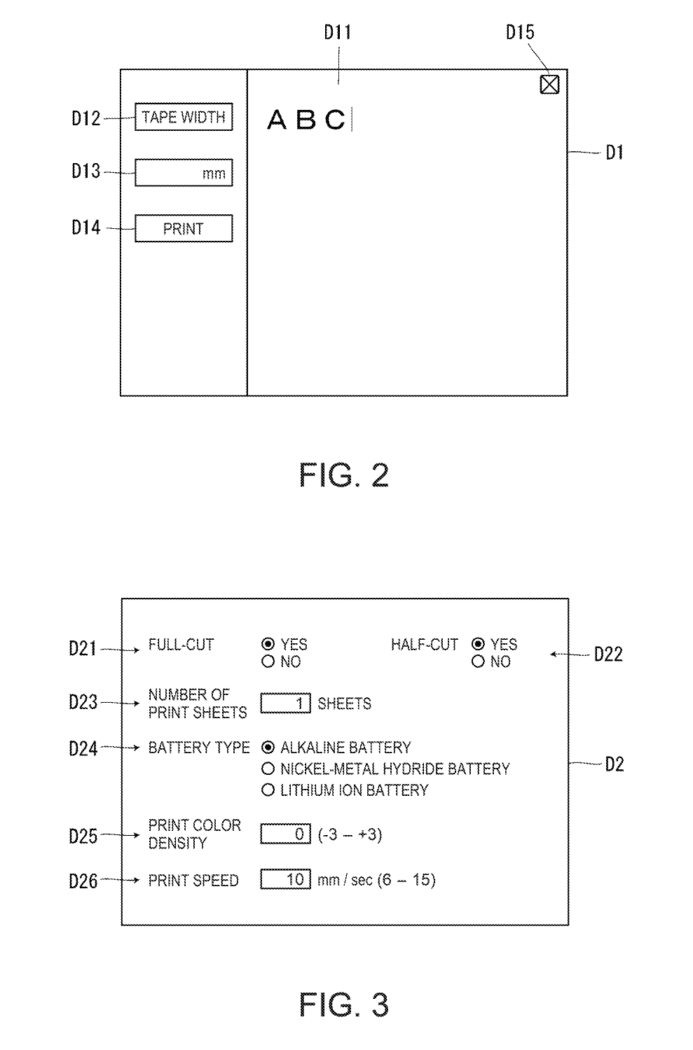

The information processing device 2 is, for example, a general-purpose personal computer, and application software (hereinafter referred to as “corresponding software”) corresponding to the tape printer 1 is installed in the information processing device 2. The information processing device 2 is provided with a PC main body 21, a keyboard 22, a mouse 23, and a display 24. The PC main body 21 incorporates a processing-side control circuit 26 (see FIG. 4) described later. The keyboard 22 and the mouse 23 accept a variety of types of input operations such as input of a character. It should be noted that the character is a concept including a letter, a symbol, a pictogram, and so on. The display 24 displays a character input screen D1 (see FIG. 2), a configuration screen D2 (see FIG. 3), and so on described later. The information processing device 2 generates print data based on the input operations accepted by the keyboard 22 and the mouse 23, and then transmits the print data thus generated to the tape printer 1.

The character input screen D1 will be described based on FIG. 2. On the character input screen D1, there are displayed a character input field D11, a tap width acquisition button D12, a tape width display field D13, a print button D14, and an end button D15. In the character input field D11, there are displayed the characters input from the keyboard 22. The tape width acquisition button D12 accepts an operation of the information processing device 2 for obtaining a tape width detected by the tape width detection sensor 117 from the tape printer 1. In the tape width display field D13, there is displayed the tape width obtained by pressing the tape width acquisition button D12. Thus, it is possible to make a user to check the tape width of the tape T housed in the tape cartridge C attacked to the tape printer 1. The print button D14 accepts an operation of making the tape printer 1 perform a print process. The end button D15 accepts an operation for ending the corresponding software.

The configuration screen D2 will be described based on FIG. 3. On the configuration screen D2, there are displayed a full-cut setting field D21, a half-cut setting field D22, a number of print sheets setting field D23, a battery type setting field D24, a print color density setting field D25, and a print speed setting field D26. It should be noted that, naturally, these fields can also be separately displayed in a plurality of screens.

In the full-cut setting field 21, whether or not full-cut is performed in the tape printer 1 is selectively displayed. The full-cut denotes cutting both of the tape main body Ta and the release paper Tb in the width direction of the tape T using a full-cutter 113 (see FIG. 4). It should be noted that, for example, the full-cut is set to “ON” by default.

In the half-cut setting field D22, whether or not half-cut is performed in the tape printer 1 is selectively displayed. The half-cut denotes cutting the tape main body Ta without cutting the release paper Tb using a half-cutter 114 (see FIG. 4). It should be noted that, for example, the half-cut is set to “ON” by default.

To the number of print sheets setting field D23, there is input the number N of print sheets. In the case in which “3” sheets, for example, is input in the number of print sheets setting field D23, the tape printer 1 performs printing on three labels continuously. It should be noted that the number N of print sheets is set to, for example, “1” by default.

In the battery type setting field D24, there is selectively displayed a plurality of types of battery (e.g., three types, namely alkaline battery, nickel-metal hydride battery, and lithium ion battery). In the case in which the AC adapter 135 is not connected to the adapter insertion port of the tape printer 1, the user selects the type of the battery 132 attached to the battery mount from among the alternatives displayed in the battery type setting field D24. It should be noted that the battery type is set to, for example, “alkaline battery” by default.

In the print color density setting field D25, there is input the print color density selected from among a plurality of levels (e.g., 7 levels from −3 to +3). The print color density is set to, for example, “0” by default. To the print color density setting field D25, the user inputs higher print color density in the case in which the print result by the tape printer 1 is pale, and inputs lower print color density in the case in which the print result is dark. The tape printer 1 changes a period of energization to a heating element provided to a print head 112 (see FIG. 4) in accordance with the print color density thus set. It should be noted that the print color density is also automatically adjusted during printing in accordance with the print temperature measured by a print temperature detection sensor 1121 (see FIG. 4).

In the print speed setting field D26, there is input the print speed selected from among a plurality of levels (e.g., 10 levels from 6 mm/sec to 15 mm/sec). The print speed is set to, for example, “10” mm/sec by default. In the case in which, for example, a faint print occurs in the print result, the user input a lower print speed to the print speed setting field D26. The tape printer 1 changes the print speed, namely feed speed of the tape T, in accordance with the print speed thus set. It should be noted that in the case in which “alkaline battery” or “nickel-metal hydride battery” is set in the battery type setting field D24, the lowest print speed is set irrespective of the selection result of the print speed setting field D26. This is because, since the alkaline battery and the nickel-metal hydride battery vary in voltage with relative ease, in the case in which the alkaline battery or the nickel-metal hydride battery is used as the power source, it is difficult for the tape printer 1 to perform printing at high speed.

The tape printer 1 and the information processing device 2 will be described based on FIG. 4. The tape printer 1 is provided with a feed mechanism 111, the print head 112, the full-cutter 113, the half-cutter 114, a feed motor 115, a cutter motor 116, the tape width detection sensor 117, an environmental temperature detection sensor 118, a print-side interface 119, a print-side control circuit 120, and a power supply 130.

The feed mechanism 111 rotates a platen roller (not shown) housed in the tape cartridge C in the state in which the tape cartridge C is mounted on the cartridge mount 101. Thus, the tape T and an ink ribbon (not shown) housed in the tape cartridge C are fed.

The print head 112 is provided with a plurality of (e.g., 384 pieces of) heating elements arranged in a direction perpendicular to the feed direction of the tape T. Each of the heating elements generates heat based on the print data received in the state in which the tape T and the ink ribbon are held between the heating element and the platen roller. Thus, the ink in the ink ribbon is transferred to the tape T, and thus the characters are printed on the tape T. Further, the print head 112 incorporates the print temperature detection sensor 1121. The print temperature detection sensor 1121 measures the print temperature, namely the heating temperature of the heating elements.

The full-cutter 113 performs the full-cut on the tape T at a position behind the part of the tape T on which printing has been performed. Thus, the part of the tape T on which printing has been performed is separated. The half-cutter 114 performs the half-cut on the tape T at, for example, a position between a tip and a print start position of the tape T. Thus, a cut is made in the tape T, and it becomes easy to peel the tape main body Ta from the release paper Tb. It should be noted that in the case of performing printing on a plurality of labels continuously, if the full-cut is set to “YES” in the full-cut setting field D21, and the half-cut is set to “YES” in the half-cut setting field D22, the full-cut and the half-cut at a position between a tip and a print start position are performed in every label. Further, if the full-cut is set to “NO” in the full-cut setting field D21, and the half-cut is set to “YES” in the half-cut setting field D22, the half-cut is performed at the position between the second label and the following labels besides the position between the tip of the tape T and the print start position of the first label.

The feed motor 115 acts as a drive source of the feed mechanism 111. The cutter motor 116 acts as a drive source of the full-cutter 113 and the half-cutter 114.

The tape width detection sensor 117 detects the type of the tape cartridge C mounted on the tape printer 1, namely the tape width of the tape T housed in the tape cartridge C. The environmental temperature detection sensor 118 detects the environmental temperature of the tape printer 1.

The print-side interface 119 transmits and receives a variety of commands and a variety of types of data with a processing-side interface 25 described later.

The print-side control circuit 120 controls each part of the tape printer 1. The print-side control circuit 120 is provided with a central processing unit (CPU) 121, a read-only memory (ROM) 122, and a random access memory (RAM) 123. The CPU 121 executes a variety of programs stored in the ROM 122 using the RAM 123 to thereby perform a variety of processes.

The power supply 130 supplies the each part of the tape printer 1 with electrical power using a commercial power source 131 or the battery 132 as the power source. The power supply 130 is provided with a power source detection sensor 133. The power source detection sensor 133 detects presence or absence of the connection of the AC adapter 135 to the adapter insertion port. In the case in which the power source detection sensor 133 has detected the connection of the AC adapter 135, the power supply 130 supplies the electrical power using the commercial power source 131 as the power source irrespective of whether or not the battery 132 is mounted. In contrast, in the case in which the power source detection sensor 133 has detected that the AC adapter 135 is not connected, the power supply 130 supplies the electrical power using the battery 132 as the power source.

Further, the power supply 130 is provided with a residual capacity detection sensor 134. The residual capacity detection sensor 134 detects the residual capacity (hereinafter referred to as “remaining battery power W_{R}”) of the battery 132. The residual capacity detection sensor 134 measures, for example, the voltage of the battery 132 as the remaining battery power W_{R}.

The information processing device 2 is provided with the keyboard 22, the mouse 23, the display 24, the processing-side interface 25, and the processing-side control circuit 26.

The processing-side interface 25 transmits and receives a variety of commands and a variety of types of data with the print-side interface 119 described above.

The processing-side control circuit 26 is provided with a CPU 261, a ROM 262, a RAM 263, and a hard disk drive (HDD) 264. The CPU 261 executes a variety of programs stored in the ROM 262 and the HDD 264 using the RAM 263 to thereby perform a variety of processes.

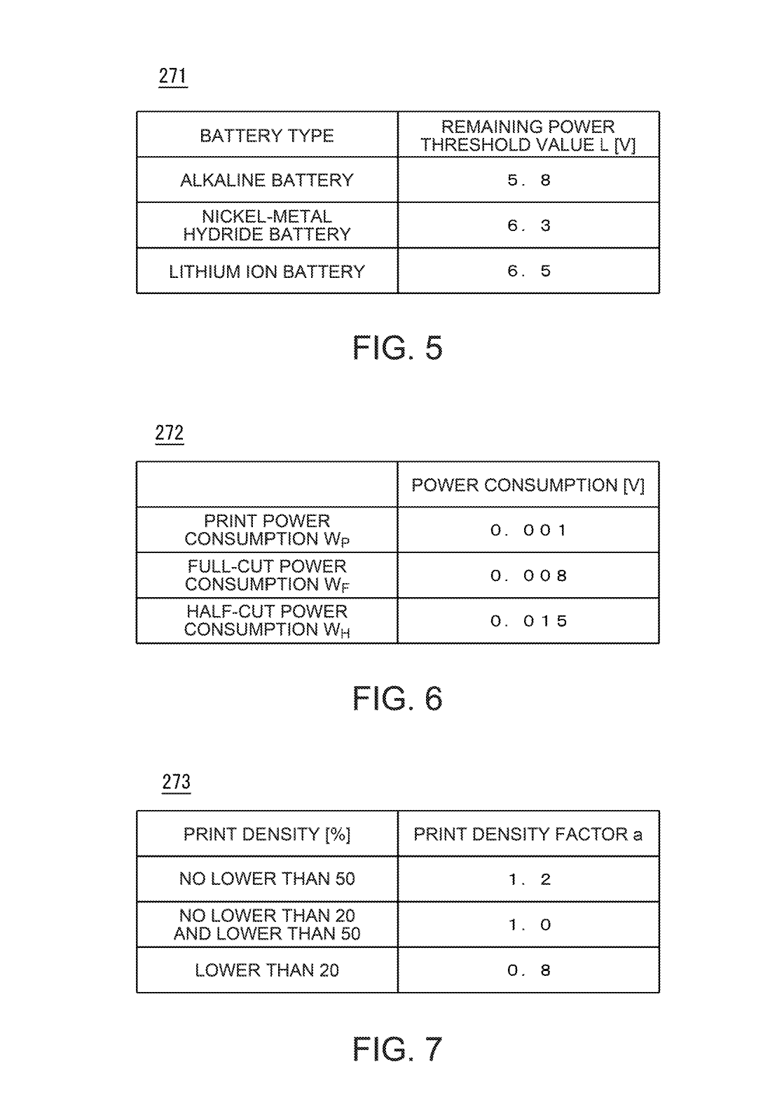

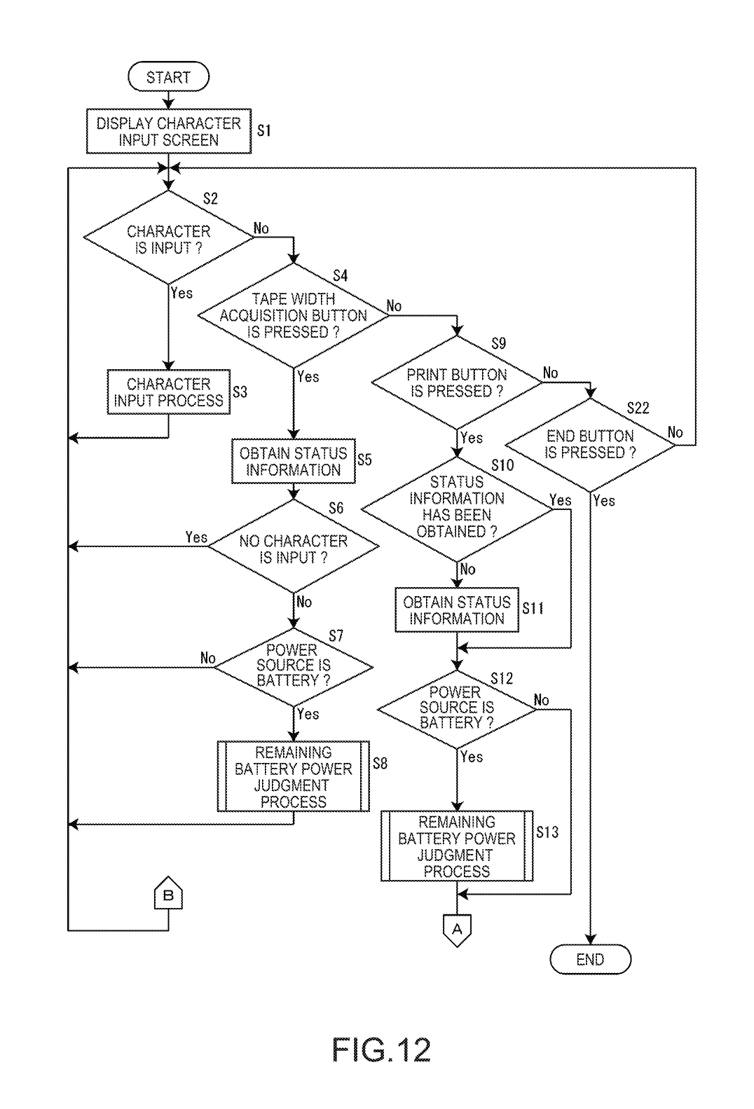

The HDD 264 stores the corresponding software. The corresponding software includes a remaining battery power judgment processing program (see FIG. 12 through FIG. 14). Further, as shown in FIG. 5 through FIG. 10, the corresponding software includes a residual capacity threshold value table 271, a power consumption table 272, a print density factor table 273, a print color density factor table 274, a print speed factor table 275, and an environmental temperature factor table 276. These programs and tables are used mainly in a remaining battery power judgment process described later. It should be noted that, naturally, the numerical values shown in the respective tables in FIG. 5 through FIG. 10 are illustrative only, but the invention is not limited to these values.

The residual capacity threshold value table 271 will be described based on FIG. 5. The residual capacity threshold value table 271 has the types (hereinafter referred to as “battery types”) of the battery 132 and the residual capacity threshold values L so as to be associated with each other. The residual capacity threshold value L is a threshold value used by the processing-side control circuit 26 when judging whether the battery 132 has the remaining battery power W_{R} with which the tape printer 1 can complete the print job in the remaining battery power judgment process. The residual capacity threshold value L of the alkaline battery is set to a lower value compared to the residual capacity threshold value L of the nickel-metal hydride battery and the residual capacity threshold value L of the lithium ion battery. This is due to the difference in discharge characteristic between the batteries. Specifically, this is because, the alkaline battery rapidly decreases in voltage when the discharge progresses compared to the nickel-metal hydride battery and the lithium ion battery.

The power consumption table 272 will be described based on FIG. 6. In the power consumption table 272, there are set the values of print power consumption W_{P}, full-cut power consumption W_{F}, and half-cut power consumption W_{H}. The print power consumption W_{P} denotes the power consumption of the battery 132 per unit length (e.g., 1 cm) of the tape T when the tape printer 1 has performed printing on the tape T. The full-cut power consumption W_{F} denotes the power consumption of the battery 132 corresponding to the full-cut performed once. The half-cut power consumption W_{H} denotes the power consumption of the battery 132 corresponding to the half-cut performed once.

The print density factor table 273 will be described based on FIG. 7. The print density factor table 273 has the print densities and the print density factors a so as to be associated with each other. The print density denotes the proportion of the number of dots corresponding to the heating elements to be heated out of the total number of dots in the print data (dot-pattern data). The higher the print density is, the larger the number of heating elements to be heated becomes, and the higher the power consumption of the battery 132 becomes. Therefore, in the print density factor table 273, the print density factor a is set to be large so that the higher the print density becomes, the higher the predicted consuming capacity W_{C} described later is calculated.

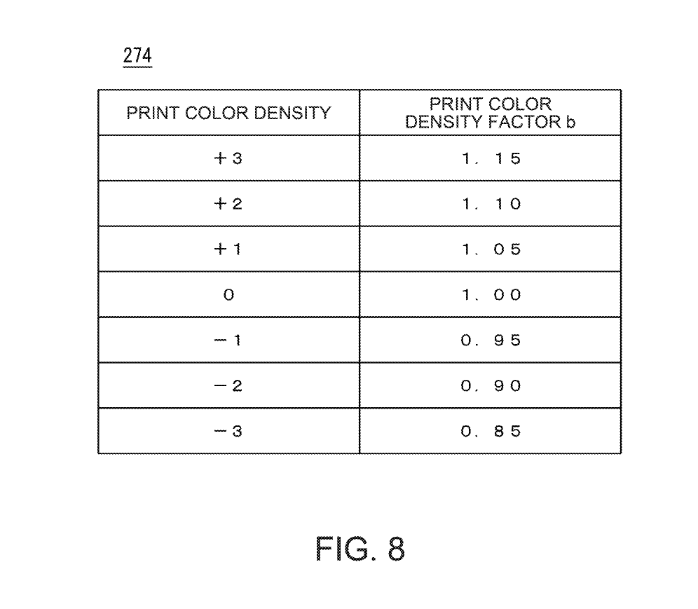

The print color density factor table 274 will be described based on FIG. 8. The print color density factor table 274 has the print color densities and the print color density factors b so as to be associated with each other. The higher the print color density becomes, the longer the energization period to the heating elements provided to the print head 112 becomes, and the higher the power consumption of the battery 132 becomes. Therefore, in the print color density factor table 274, the print color density factor b is set to be large so that the higher the print color density becomes, the higher the predicted consuming capacity W_{C} is calculated.

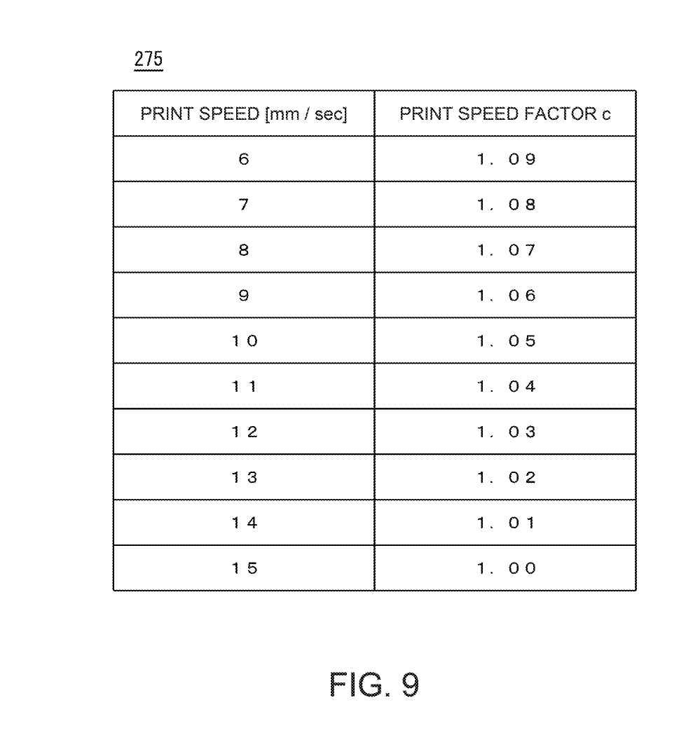

The print speed factor table 275 will be described based on FIG. 9. The print speed factor table 275 has the print speed values and the print speed factors c so as to be associated with each other. The higher the print speed becomes, the higher the heat efficiency becomes to make it sufficient for the energization period to the heating elements to be shorter, and the lower the power consumption of the battery 132 becomes. Therefore, in the print speed factor table 275, the print speed factor c is set to be small so that the higher the print speed becomes, the lower the predicted consuming capacity W_{C} is calculated.

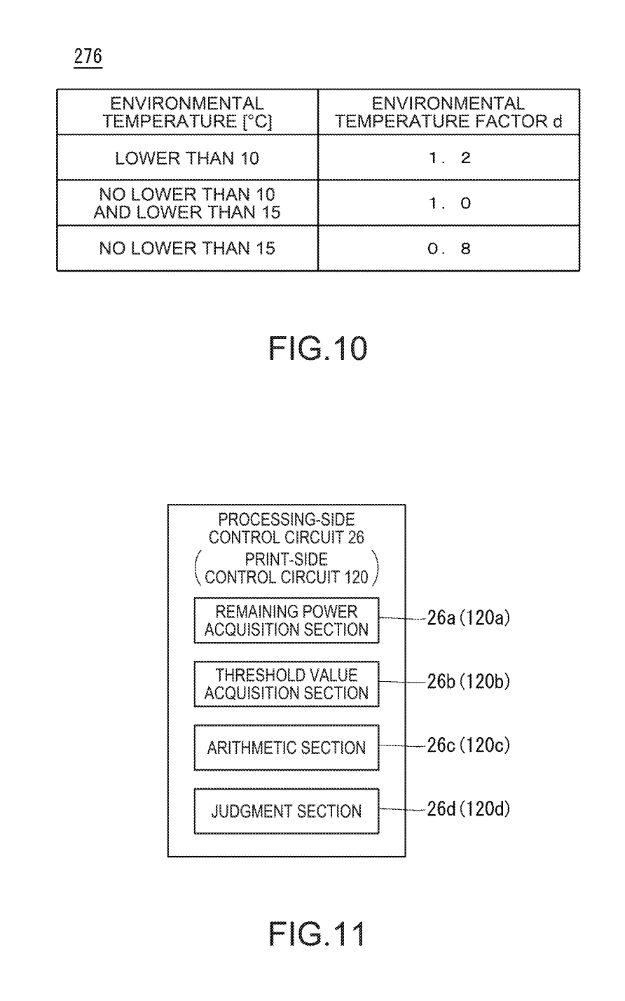

The environmental temperature factor table 276 will be described based on FIG. 10. The environmental temperature factor table 276 has the environmental temperature values and the environmental temperature factors d so as to be associated with each other. The higher the environmental temperature becomes, the shorter it is sufficient for the energization period to be, and the lower the power consumption of the battery 132 becomes. Therefore, in the environmental temperature factor table 276, the environmental temperature factor d is set to be small so that the higher the environmental temperature becomes, the lower the predicted consuming capacity W_{C} is calculated.

A functional configuration of the processing-side control circuit 26 will be described based on FIG. 11. The processing-side control circuit 26 is provided with a residual capacity acquisition section 26a, a threshold value acquisition section 26b, an arithmetic section 26c, and a judgment section 26d. These functional sections are each realized by cooperation of the hardware constituting the processing-side control circuit 26 and the software such as the remaining battery power judgment processing program.

The residual capacity acquisition section 26a obtains the remaining battery power W_{R} based on the output from the residual capacity detection sensor 134 of the tape printer 1.

The threshold value acquisition section 26b looks up the residual capacity threshold value table 271 to obtain the residual capacity threshold value L associated with the battery type set in the battery type setting field D24.

The arithmetic section 26c calculates the predicted consuming capacity W_{C} of the battery 132 to be consumed by the execution of the print job based on the following formula.

W_{C}={(a×b×c×d×W_{P}×D)+(W_{F}×M_{F})+(W_{H}×M_{H})}×N
W_{C}: predicted consuming capacity [V]
a: print density factor
b: print color density factor
c: print speed factor
d: environmental temperature factor
W_{P}: print power consumption [V/cm]
D: print length [cm]
W_{F}: full-cut power consumption [V/times]
M_{F}: Number of times of full-cut [times]
W_{H}: half-cut power consumption [V/times]
M_{H}: Number of times of half-cut [times]
N: number of labels printed in a print job

As the print density factor a, the arithmetic section 26c uses a value associated with the print density of the print data generated in the print density factor table 273. As the print color density factor b, the arithmetic section 26c uses a value associated with the print color density adjusted in accordance with the print color density set in the print color density setting field D25 or the print temperature detected by the print temperature detection sensor 1121 in the print color density factor table 274. As the print speed factor c, the arithmetic section 26c uses a value associated with the print speed set in the print speed setting field D26 in the print speed factor table 275. As the environmental temperature factor d, the arithmetic section 26c uses a value associated with the environmental temperature detected by the environmental temperature detection sensor 118 in the environmental temperature factor table 276.

As the print power consumption W_{P}, the arithmetic section 26c uses the value set in the power consumption table 272. As the print length D (the length of the tape T fed), the arithmetic section 26c uses the value calculated based on the characters and so on input.

As the full-cut power consumption W_{F}, the arithmetic section 26c uses the value set in the power consumption table 272. As the number M_{F} of times of full-cut, the arithmetic section 26c uses “1” in the case in which “YES” is selected in the full-cut setting field D21, or uses “0” in the case in which “NO” is selected in the full-cut setting field D21.

As the half-cut power consumption W_{H}, the arithmetic section 26c uses the value set in the power consumption table 272. As the number M_{H} of times of half-cut, the arithmetic section 26c uses “1” in the case in which “YES” is selected in the half-cut setting field D22, or uses “0” in the case in which “NO” is selected in the half-cut setting field D22.

As the number N of print sheets, the arithmetic section 26c uses the value input in the number of print sheets setting field D23.

The judgment section 26d judges whether or not the battery 132 has the remaining battery power W_{R} with which the tape printer 1 can complete the print job based on the remaining battery power W_{R} detected by the residual capacity detection sensor 134 and the predicted consuming capacity W_{C} calculated by the arithmetic section 26c. Specifically, the judgment section 26d judges whether or not the difference (hereinafter referred to as a “predicted residual capacity W_{D}”) obtained by subtracting the predicted consuming capacity W_{C} from the remaining battery power W_{R} is equal to or higher than the residual capacity threshold value L obtained by the threshold value acquisition section 26b.

Based on FIG. 12 through FIG. 14, the processing sequence of the processing-side control circuit 26 after starting up the corresponding software will be described. After the corresponding software is started up, the processing-side control circuit 26 makes the display 24 display the character input screen D1 in the step S1.

In the step S2, the processing-side control circuit 26 judges whether or not a character has been input from the keyboard 22. In the case in which the processing-side control circuit 26 has judged that the character has been input from the keyboard 22 (Yes in the step S2), the process proceeds to the step S3. In contrast, in the case in which the processing-side control circuit 26 has judged that the character has not been input from the keyboard 22 (No in the step S2), the process proceeds to the step S4.

In the step S3, the processing-side control circuit 26 performs a character input process. Specifically, the processing-side control circuit 26 stores code data corresponding to the character input from the keyboard 22 in the RAM 263. Further, the processing-side control circuit 26 makes the character thus input be displayed in the character input field D11 based on the code data thus stored. When the processing-side control circuit 26 performs the character input process, the process returns to the step S2.

In the step S4, the processing-side control circuit 26 judges whether or not the tape width acquisition button D12 has been pressed. In the case in which the processing-side control circuit 26 has judged that the tape width acquisition button D12 has been pressed (Yes in the step S4), the process proceeds to the step S5. In contrast, in the case in which the processing-side control circuit 26 has judged that the tape width acquisition button D12 has not been pressed (No in the step S4), the process proceeds to the step S9.

In the step S5, the processing-side control circuit 26 transmits a status information request to the tape printer 1, and then obtains the status information transmitted from the tape printer 1 in response to the status information request. The status information includes the environmental temperature, the print temperature, the type of the power source, the remaining battery power W_{R}, and so on detected by the respective sensors besides the tape width detected by the tape width detection sensor 117. It should be noted that on this occasion, since the tape printer 1 is in a no-load state, the remaining battery power W_{R}, namely the voltage value, detected by the residual capacity detection sensor 134 becomes higher than the voltage value detected by the residual capacity detection sensor 134 during the print process as a loaded state in some cases. Therefore, it is also possible to, for example, apply a voltage to the print head 112 to the extent that printing is not performed on the tape T, so that the voltage is accurately detected by the residual capacity detection sensor 134. The same also applies to the period of obtaining the status information in the step S11 described later.

In the step S6, the processing-side control circuit 26 judges whether or not no character has been input based on the presence or absence of the code data stored in the RAM 263. In the case in which the processing-side control circuit 26 has judged that some character has been input (No in the step S6), the process proceeds to the step S7. In contrast, in the case in which the processing-side control circuit 26 has judged that no character has been input (Yes in the step S6), the process returns to the step S2.

In the step S7, the processing-side control circuit 26 judges whether or not the type of the power source is the battery 132 based on the type of the power source included in the status information. In the case in which the processing-side control circuit 26 has judged that the type of the power source is the battery 132 (Yes in the step S7), the process proceeds to the step S8. In contrast, in the case in which the processing-side control circuit 26 has judged that the type of the power source is not the battery 132 (No in the step S7), the process returns to the step S2.

In the step S8, the processing-side control circuit 26 performs the remaining battery power judgment process. After the processing-side control circuit 26 performs the remaining battery power judgment process, the process returns to the step S2.

In the step S9, the processing-side control circuit 26 judges whether or not the print button D14 has been pressed. In the case in which the processing-side control circuit 26 has judged that the print button D14 has been pressed (Yes in the step S9), the process proceeds to the step S10. In the case in which the processing-side control circuit 26 has judged that the print button D14 has not been pressed (No in the step S9), the process proceeds to the step S22.

In the step S10, the processing-side control circuit 26 judges whether or not the status information has been obtained. In the case in which the processing-side control circuit 26 has judged that the status information has not been obtained (No in the step S10), the process proceeds to the step S11. In contrast, in the case in which the processing-side control circuit 26 has judged that the status information has already been obtained (Yes in the step S10), the process proceeds to the step S12.

In the step S11, the processing-side control circuit 26 transmits the status information request to the tape printer 1, and then obtains the status information transmitted from the tape printer 1 in response to the status information request.

In the step S12, the processing-side control circuit 26 judges whether or not the type of the power source is the battery 132 based on the type of the power source included in the status information. In the case in which the processing-side control circuit 26 has judged that the type of the power source is the battery 132 (Yes in the step S12), the process proceeds to the step S13. In contrast, in the case in which the processing-side control circuit 26 has judged that the type of the power source is not the battery 132 (No in the step S12), the process proceeds to the step S14.

In the step S13, the processing-side control circuit 26 performs the remaining battery power judgment process.

After the processing-side control circuit 26 performs the remaining battery power judgment process, the process proceeds to the step S14.

In the step S14, the processing-side control circuit 26 transmits the print data to the tape printer 1, and at the same time, instructs the tape printer 1 to start the print job. The tape printer 1 performs the print process based on the print data received.

In the step S15, the processing-side control circuit 26 initializes a variable n to “1.”

In the step S16, the processing-side control circuit 26 transmits the status information request to the tape printer 1 which is performing the print process, and then obtains the status information transmitted from the tape printer 1 in response to the status information request. The processing-side control circuit 26 updates the status information having already been obtained to the status information obtained most recently.

In the step S17, the processing-side control circuit 26 judges whether or not a print completion notification of the n-th label has been received from the tape printer 1. In the case in which the processing-side control circuit 26 has judged that the print completion notification of the n-th label has been received (Yes in the step S17), the process proceeds to the step S18. In contrast, in the case in which the processing-side control circuit 26 has judged that the print completion notification of the n-th label has not been received (No in the step S17), the process returns to the step S16.

In the step S18, the processing-side control circuit 26 judges whether or not the type of the power source is the battery 132 based on the type of the power source included in the status information. In the case in which the processing-side control circuit 26 has judged that the type of the power source is the battery 132 (Yes in the step S18), the process proceeds to the step S19. In contrast, in the case in which the processing-side control circuit 26 has judged that the type of the power source is not the battery 132 (No in the step S18), the process proceeds to the step S20.

In the step S19, the processing-side control circuit 26 performs the remaining battery power judgment process. After the processing-side control circuit 26 performs the remaining battery power judgment process, the process proceeds to the step S20.

In the step S20, the processing-side control circuit 26 judges whether or not the print job has been completed, namely whether or not the variable n is equal to the number N of print sheets. In the case in which the processing-side control circuit 26 has judged that the variable n is equal to the number N of print sheets (Yes in the step S20), the process returns to the step S2. In contrast, in the case in which the processing-side control circuit 26 has judged that the variable n is not equal to the number N of print sheets (No in the step S20), the process proceeds to the step S21.

In the step S21, the processing-side control circuit 26 adds “1” to the variable n, and the process returns to the step S16.

In the step S22, the processing-side control circuit 26 judges whether or not the end button D15 has been pressed. In the case in which the processing-side control circuit 26 has judged that the end button D15 has been pressed (Yes in the step S22), the process terminates the series of processes to close the corresponding software. In contrast, in the case in which the processing-side control circuit 26 has judged that the end button D15 has not been pressed (No in the step S22), the process returns to the step S2.

As described above, after the tape width acquisition button D12 is pressed, the processing-side control circuit 26 performs the remaining battery power judgment process (S8). Further, after the print button D14 is pressed, and before the print process is performed, the processing-side control circuit 26 performs the remaining battery power judgment process (S13). Further, during the execution of the print process, the processing-side control circuit 26 performs the remaining battery power judgment process (S19) every time one label is printed.

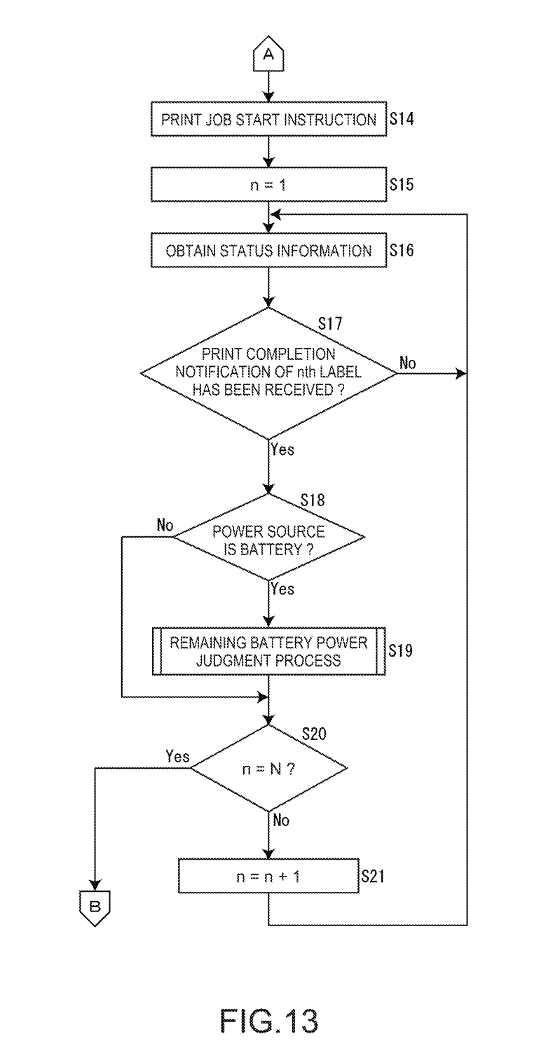

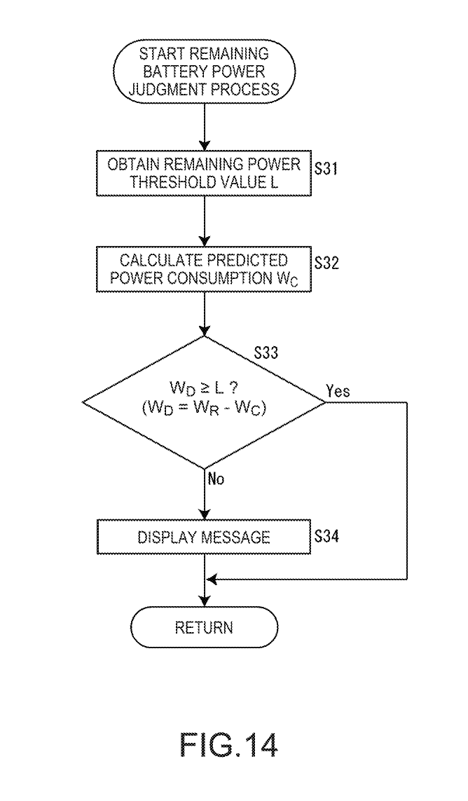

The remaining battery power judgment process performed in the step S8, the step S13, and the step S19 in the flowchart shown in FIG. 12 and FIG. 13 will be described with reference to FIG. 14.

In the step S31, the residual capacity acquisition section 26a of the processing-side control circuit 26 obtains the residual capacity threshold value L.

In the step S32, the arithmetic section 26c of the processing-side control circuit 26 calculates the predicted consuming capacity W_{C}. Here, in the case of the remaining battery power judgment process performed in the step S19, the arithmetic section 26c uses (N−n) (N represents the number of print sheets, n represents the variable n) instead of N in the above formula for calculating the predicted consuming capacity W_{C}. In other words, as the predicted consuming capacity W_{C}, the arithmetic section 26c calculates the value consumed by the execution of the print job for performing printing on the (n+1)-th label and the following labels which has not yet been printed. Further, even in the case in which the power consumption of the battery 132 varies due to the adjustment of the print color density during the print process, in the remaining battery power judgment process to be performed in the step S19, the predicted consuming capacity W_{C} is calculated based on the print color density factor b associated with the print color density thus updated. Therefore, the predicted consuming capacity W_{C} is appropriately calculated.

In the step S33, the judgment section 26d of the processing-side control circuit 26 judges whether or not the predicted residual capacity W_{D} is equal to or higher than the residual capacity threshold value L. Here, as described above, the predicted residual capacity W_{D} is a difference obtained by subtracting the predicted consuming capacity W_{C} from the remaining battery power W_{R}. In the remaining battery power judgment process in the step S8, as the remaining battery power W_{R}, there is used what is included in the status information obtained in the step S5. Further, in the remaining battery power judgment process in the step S13, as the remaining battery power W_{R}, there is used what is included in the status information obtained in the step S5 or the step S11. In contrast, in the remaining battery power judgment process in the step S19, there is used what is included in the status information obtained in the step S16 (the status information obtained in the most recent step S16 in the case in which the step S16 is repeated). Therefore, the remaining battery power W_{R} varying in the print process can be obtained in real time.

In the case in which the judgment section 26d has judged that the predicted residual capacity W_{D} is lower than the residual capacity threshold value L (No in the step S33), the process proceeds to the step S34. In contrast, in the case in which the judgment section 26d has judged that the predicted residual capacity W_{D} is equal to or higher than the residual capacity threshold value L (Yes in the step S33), the process returns to the flowchart shown in FIG. 12 and the FIG. 13.

The processing-side control circuit 26 makes the display 24 display the message in the step S34, and then the process returns to the flowchart shown in FIG. 12 and FIG. 13. The content of the message is, for example, “BATTERY VOLTAGE IS LOW. PLEASE REPLACE THE BATTERY.”

As described above, according to the information processing device 2 related to the present embodiment, there are provided the residual capacity acquisition section 26a, the arithmetic section 26c, and the judgment section 26d. The residual capacity acquisition section 26a obtains the remaining battery power W_{R} of the battery 132 as the power source of the tape printer 1. The arithmetic section 26c calculates the predicted consuming capacity W_{C} of the battery 132 to be consumed by the execution of the print job. The judgment section 26d judges whether or not the battery 132 has the remaining battery power W_{R} with which the tape printer 1 can complete the print job based on the remaining battery power W_{R} and the predicted consuming capacity W_{C}.

According to this configuration, based on the predicted consuming capacity W_{C} calculated by the arithmetic section 26c, whether or not the battery 132 has the remaining battery power W_{R} with which the tape printer 1 can complete the print job is judged by the judgment section 26d. Thus, even in the case in which the predicted consuming capacity W_{C} varies in accordance with the content of the print job, whether or not the battery 132 has the remaining battery power W_{R} with which the tape printer 1 can complete the print job can appropriately be judged. Therefore, according to the present configuration, it is possible to prevent the tape printer 1 from faultily judging that the print job can be completed despite that tape printer 1 cannot complete the print job due to the shortage of the remaining battery power W_{R}. Therefore, it is possible to prevent the case in which the remaining battery power W_{R} becomes short in the middle of the print process due to the increase in power consumption of the battery 132 as in the case of performing printing on a plurality of labels continuously, and thus printing stops in the middle of the print process. In particular, in the case of serial number printing, if printing stops in the middle of the print process, in the case of a model which cannot automatically resume printing in the middle of the print process, it is required for the user to check the last number printed completely, and then perform setting so that printing resumes from the label with the next number to the last number. The present configuration is particularly advantageous in the point that it is possible to prevent such a trouble from occurring.

Further, according to the information processing device 2 related to the present embodiment, the arithmetic section 26c calculates the predicted consuming capacity W_{C} based on the print density in the print job.

According to this configuration, even in the case in which the predicted consuming capacity W_{C} varies in accordance with the print density, the predicted consuming capacity W_{C} can appropriately be calculated.

Further, according to the information processing device 2 related to the present embodiment, the arithmetic section 26c calculates the predicted consuming capacity W_{C} based on the number of times of the cutting process for cutting the tape T in the print job, namely the number of times of the full-cut and the number of times of the half-cut.

According to this configuration, even in the case in which the predicted consuming capacity W_{C} varies in accordance with the number of times of the cutting process, the predicted consuming capacity W_{C} can appropriately be calculated.

Further, according to the information processing device 2 related to the present embodiment, there is further provided the threshold value acquisition section 26b for obtaining the residual capacity threshold value L. Further, as the judgment on whether or not the battery 132 has the remaining battery power W_{R} with which the tape printer 1 can complete the print job, the judgment section 26d makes the judgment on whether or not the predicted residual capacity W_{D} as the difference obtained by subtracting the predicted consuming capacity W_{C} from the remaining battery power W_{R} is equal to or higher than the residual capacity threshold value L.

According to this configuration, in the case in which the predicted residual capacity W_{D} is equal to or higher than the residual capacity threshold value L, it is judged that the battery 132 has the remaining battery power W_{R} with which the tape printer 1 can complete the print job. Further, in the case in which the predicted residual capacity W_{D} is lower than the residual capacity threshold value L, it is judged that the battery 132 fails to have the remaining battery power W_{R} with which the tape printer 1 can complete the print job.

Further, according to the information processing device 2 related to the present embodiment, the threshold value acquisition section 26b obtains the residual capacity threshold value L different between the types of the battery 132.

According to this configuration, as the residual capacity threshold value L, the value added with the discharge characteristic of the battery 132 can be obtained.

Further, according to the information processing device 2 related to the present embodiment, the residual capacity acquisition section 26a obtains the remaining battery power W_{R} while printing the n-th label in the print job for printing a plurality of labels. As the predicted consuming capacity W_{C}, the arithmetic section 26c calculates the value consumed by the execution of the print job for performing printing on the (n+1)-th label and the following labels. The judgment section 26d judges whether or not the battery 132 has the remaining battery power W_{R} with which the tape printer 1 can complete the print job for performing printing on the (n+1)-th label and the following labels based on the remaining battery power W_{R} obtained while printing the n-th label and the predicted consuming capacity W_{C}.

According to this configuration, the remaining battery power W_{R} is obtained in real time while performing printing on the plurality of labels. Therefore, according to the present configuration, whether or not the battery 132 has the remaining battery power W_{R} with which the tape printer 1 can complete the print job can more appropriately be judged.

Further, according to the information processing device 2 related to the present embodiment, there is further provided a display 24 for displaying a message in the case in which it has been judged that the battery 132 fails to have the remaining battery power W_{R} with which the tape printer 1 can complete the print job.

According to the present configuration, it is possible to notify the user of the fact that the battery 132 fails to have the remaining battery power W_{R} with which the tape printer 1 can complete the print job.

It should be noted that the print head 112 is an example of a “print section.” The information processing device 2 is an example of a “judgment device.”

It is obvious that the invention is not limited to the embodiment described above, but can adopt a variety of configurations within the scope and the spirit of the invention. For example, the present embodiment can be modified into the following configuration.

The arithmetic section 26c is not limited to the configuration of calculating the predicted consuming capacity W_{C} based on the formula described above, but it is also possible to, for example, eliminate some of the terms of the formula described above, or add other terms in accordance with the characteristic of the tape printer 1.

The judgment section 26d is not limited to the configuration of making the judgment on whether or not the predicted residual capacity W_{D} is equal to or higher than the residual capacity threshold value L, as the judgment on whether or not the battery 132 has the remaining battery power W_{R} with which the tape printer 1 can complete the print job. It is also possible for the judgment section 26d to judge that the battery 132 has the remaining battery power W_{R} with which the print job can be completed if the predicted consuming capacity W_{C} is lower than 0.5 V in the case in which, for example, the remaining battery power W_{R} is no lower than 6.0 V and lower than 6.5 V, and judge that the battery 132 has the remaining battery power W_{R} with which the print job can be completed if the predicted consuming capacity W_{C} is lower than 1.0 V in the case in which the remaining battery power W_{R} is no lower than 6.5 V and lower than 7.0 V.

It is also possible for the information processing device 2 to be provided with, for example, a sound output device for giving a message with a sound instead of the display device such as the display 24 as an annunciation section.

It is also possible for the print-side control circuit 120 of the tape printer 1 to have a configuration functioning similarly to the processing-side control circuit 26 of the information processing device 2. In other words, it is also possible for the print-side control circuit 120 to have a configuration (see FIG. 11) functionally provided with a residual capacity acquisition section 120a, a threshold value acquisition section 120b, an arithmetic section 120c, and a judgment section 120d. In this case, it is preferable for the tape printer 1 to be provided with the annunciation section for giving a message.

The invention is not limited to the tape printer 1, but can also be applied to a printer for performing printing on other printing media such as roll paper.

It is also possible for the invention to be provided as a program (e.g., the remaining battery power judgment processing program described above) for making the information processing device 2 function as the judgment device according to the invention, and a recording medium (e.g., a CD-ROM, a flash memory) storing the program.

### CROSS REFERENCE TO RELATED APPLICATIONS

This application claims priority to Japanese Patent Application No. 2015-253625 filed on Dec. 25, 2015 the entire contents of which are incorporated by reference herein.

What is claimed is:

1. A judgment device comprising:
a residual capacity acquisition section adapted to obtain a remaining battery power of a battery as a power source of a printer;
an arithmetic section adapted to calculate a predicted consuming capacity of the battery consumed by execution of a print job; and
a judgment section adapted to judge whether or not the battery has the remaining battery power, with which the printer can complete the print job, based on the remaining battery power and the predicted consuming capacity.

2. The judgment device according to claim 1, wherein
the arithmetic section calculates the predicted consuming capacity based on a print density in the print job.

3. The judgment device according to claim 1, wherein
the arithmetic section calculates the predicted consuming capacity based on a number of times of a cutting process adapted to cut a print medium in the print job.

4. The judgment device according to claim 1, further comprising:
a threshold value acquisition section adapted to obtain a residual capacity threshold value,
wherein the judgment section makes a judgment on whether or not a predicted residual capacity as a difference obtained by subtracting the predicted consuming capacity from the remaining battery power is one of equal to and higher than the residual capacity threshold value as the judgment on whether or not the battery has the remaining battery power with which the printer can complete the print job.

5. The judgment device according to claim 4, wherein
the threshold acquisition section obtains the residual capacity threshold value different between types of the battery.

6. The judgment device according to claim 1, wherein
the residual capacity acquisition section obtains the remaining battery power while performing printing on n-th label (n is an integer no smaller than 1) out of the print job of performing printing on a plurality of labels,
the arithmetic section calculates a value consumed by execution of the print job of performing printing on an (n+1)-th label and following labels as the predicted consuming capacity, and
the judgment section judges whether or not the battery has the remaining battery power with which the printer can complete the print job of performing printing on the (n+1)-th label and the following labels based on the remaining battery power obtained while performing printing on the n-th label, and the predicted consuming capacity.

7. The judgment device according to claim 1, further comprising:
an annunciation section adapted to give a message in a case in which the judgment section judges that the battery fails to have the remaining battery power with which the printer can complete the print job.

8. A program making an information processing device function as the judgment device according to claim 1.

9. A program making an information processing device function as the judgment device according to claim 2.

10. A program making an information processing device function as the judgment device according to claim 3.

11. A program making an information processing device function as the judgment device according to claim 4.

12. A program making an information processing device function as the judgment device according to claim 5.

13. A program making an information processing device function as the judgment device according to claim 6.

14. A program making an information processing device function as the judgment device according to claim 7.

15. A judgment method in a judgment device comprising:
obtaining a remaining battery power of a battery as a power source of a printer;
calculating a predicted consuming capacity of the battery consumed by execution of a print job; and
judging whether or not the battery has the remaining battery power, with which the printer can complete the print job, based on the remaining battery power and the predicted consuming capacity.

16. A printer comprising:
a printing section adapted to perform printing on a print medium;
a residual capacity acquisition section adapted to obtain a remaining battery power of a battery as a power source;
an arithmetic section adapted to calculate a predicted consuming capacity of the battery consumed by execution of a print job; and
a judgment section adapted to judge whether or not the battery has the remaining battery power, with which the print job cab be completed, based on the remaining battery power and the predicted consuming capacity.
